(19) United States
(12) Patent Application Publication
(10) Pub. No.: US 2020/0350386 A1
(43) Pub. Date: Nov. 5, 2020

(54) DISPLAY SCREEN AND TERMINAL

(71) Applicant: HUAWEI TECHNOLOGIES CO., LTD., Shenzhen, Guangdong (CN)

(72) Inventors: Chiaching CHU, Dongguan (CN); Xuhui TIAN, Dongguan (CN)

(21) Appl. No.: 16/771,585

(22) PCT Filed: Feb. 26, 2018
(86) PCT No.: PCT/CN2018/077269

§ 371 Date: Jun. 10, 2020

(30) Foreign Application Priority Data
Dec. 11, 2017 (CN) 201711311692.1

(51) Int. Cl. H01L 27/32; H01L 51/52

(52) U.S. Cl. CPC H01L 27/3272; H01L 27/3218; H01L 27/3216; H01L 51/5253

(57) ABSTRACT

Embodiments relate to a display screen, including a cathode metal layer, an encapsulating layer disposed on an upper surface of the cathode metal layer, and an organic light-emitting layer disposed on a lower surface of the cathode metal layer. The organic light-emitting layer includes a non-light-emitting region and a plurality of light-emitting regions. The display screen further includes a light shielding layer. The light shielding layer is disposed on an upper surface of the encapsulating layer, and the light shielding layer is used to shield the non-light-emitting region of the organic light-emitting layer.

This application claims priority from PCT Application No. CN2018/077269 filed 26 Feb. 2018 and entitled “DISPLAY SCREEN AND TERMINAL”, which claims priority from Chinese Patent Application No. 201711311692.1, filed with the Chinese Patent Office on Dec. 11, 2017 and entitled “OLED DISPLAY SCREEN”, each of which are incorporated herein by reference in their entirety.

### TECHNICAL FIELD

This application relates to the display screen field, and in particular, to a display screen and a terminal.

### BACKGROUND

A structure of an existing organic light-emitting diode (Organic Light-Emitting Diode, OLED) display screen is shown in FIG. 1. The OLED display screen includes an encapsulating layer, a cathode, an electron inject layer, an electron transport layer, an emissive layer, a hole transport layer, a hole inject layer, an anode, and a substrate. The electron inject layer, the electron transport layer, the emissive layer, the hole transport layer, and the hole inject layer are collectively referred to as an organic light-emitting layer. The cathode is made of a metal material, and is also referred to as a cathode metal layer. Because of existence of the cathode metal layer, ambient light outside the display screen is reflected. Consequently, a panel contrast decreases, and a display effect is affected. A schematic diagram of a process in which the cathode metal layer reflects the ambient light is shown in FIG. 2.

To resolve a problem that the cathode metal layer reflects the ambient light, currently, a common solution is to dispose a circular polarizer outside the encapsulating layer, so that the light reflected by the cathode metal layer cannot be received from outside the OLED structure. A structure thereof is shown in FIG. 3. However, the structure may have the following problems.

(1) Transmittance of a display screen decreases, and transmittance of the polarizer is less than 50%. (2) A thickness of the circular polarizer is about 100 micrometers, which greatly increases a thickness of the display screen and is not conducive to screen bending.

### SUMMARY

An objective of embodiments of the present invention is to resolve a prior-art problem of a relatively large thickness caused by a polarizer.

According to a first aspect, an embodiment of the present invention provides a display screen. The display screen includes a cathode metal layer, an encapsulating layer disposed on an upper surface of the cathode metal layer, and an organic light-emitting layer disposed on a lower surface of the cathode metal layer. The organic light-emitting layer includes a non-light-emitting region and a plurality of light-emitting regions. The display screen further includes a light shielding layer. The light shielding layer is disposed on an upper surface of the encapsulating layer, and is used to shield the non-light-emitting region of the organic light-emitting layer. Disposition of the light shielding layer can effectively reduce ambient-light reflection from the cathode metal layer, and allows a polarizer layer to be omitted, thereby resolving a problem of ambient-light reflection from the cathode metal layer by using a relatively small thickness, and avoiding a problem of relatively low transmittance caused by a polarizer.

In a possible implementation, an optical density of the light shielding layer is greater than or equal to 3.0. The optical density of the light shielding layer can effectively shield against ambient light.

In a possible implementation, a thickness of the light shielding layer is 1 micrometer. Disposition of the light shielding layer omits the polarizer layer and reduces a thickness of the display screen, so that a screen bending capability can be improved.

In a possible implementation, a material of the light shielding layer is chromium or acryl resin.

According to a second aspect, an embodiment of the present invention provides a terminal, including the display screen according to the first aspect.

In a possible implementation, the terminal is a mobile phone, a wearable device, or a tablet.

According to a third aspect, an embodiment of the present invention provides a display screen, including an encapsulating layer, a light shielding layer, a cathode metal layer, and an organic light-emitting layer. The light shielding layer is located between the encapsulating layer and the cathode metal layer, the organic light-emitting layer is located on a lower surface of the cathode metal layer, the organic light-emitting layer includes a non-light-emitting region and a plurality of light-emitting regions, and the light shielding layer is used to shield the non-light-emitting region of the organic light-emitting layer. Disposition of the light shielding layer can effectively reduce ambient-light reflection from the cathode metal layer, and allows a polarizer layer to be omitted, thereby resolving a problem of ambient-light reflection from the cathode metal layer by using a relatively small thickness, and avoiding a problem of relatively low transmittance caused by a polarizer.

In a possible implementation, an optical density of the light shielding layer is greater than or equal to 3.0. The optical density of the light shielding layer can effectively shield against ambient light.

In a possible implementation, a thickness of the light shielding layer is 1 micrometer. Disposition of the light shielding layer omits the polarizer layer and reduces a thickness of the display screen, so that a screen bending capability can be improved.

In a possible implementation, a material of the light shielding layer is chromium or acryl resin.

According to a fourth aspect, an embodiment of the present invention provides a terminal, including the display screen according to the third aspect.

In a possible implementation, the terminal is a mobile phone, a wearable device, or a tablet.

In possible implementations, the display screen mentioned in the foregoing implementations is an organic light-emitting diode display screen.

In some embodiments of the present invention, a light shielding layer is added. This can effectively reduce ambient-light reflection from the cathode metal layer, and allow omission of a polarizer layer, thereby resolving a problem of ambient-light reflection from the cathode metal layer by using a relatively small thickness, and avoiding a problem of relatively low transmittance caused by a polarizer.

### BRIEF DESCRIPTION OF DRAWINGS

FIG. 1 is a schematic structural diagram of an OLED display screen in the prior art;

FIG. 2 is a schematic diagram of a process of reflecting ambient light by a cathode metal layer of an OLED display screen in the prior art;

FIG. 3 is a schematic structural diagram of an OLED to which a circular polarizer is added in the prior art;

FIG. 4 is a schematic structural diagram of an OLED display screen according to an embodiment of the present invention;

FIG. 5 is a schematic diagram of an OLED pixel structure;

FIG. 6 is a schematic top view of a display screen;

FIG. 7 is a schematic structural diagram of an OLED display screen that has a light shielding layer according to an embodiment of the present invention;

FIG. 8 is a schematic structural diagram of another OLED display screen that has a light shielding layer according to an embodiment of the present invention;

FIG. 9 is a schematic diagram of light mixing caused by an increase in an aperture ratio; and

FIG. 10 is a schematic diagram of shielding a light mixing region by using a light shielding layer to improve an aperture ratio.

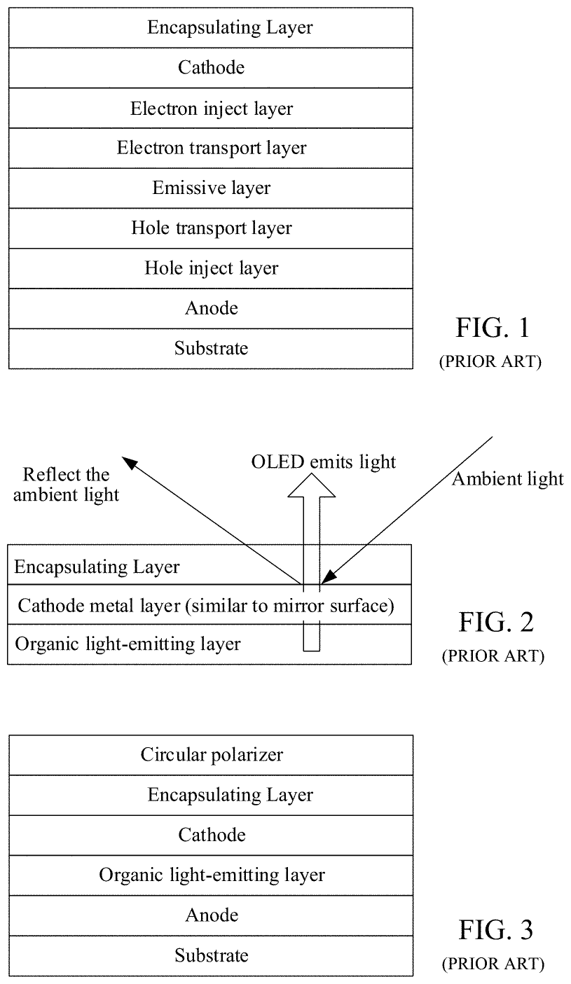

### DESCRIPTION OF EMBODIMENTS

To make the objective, technical solutions, and advantages of the embodiments of the present invention clearer, the following clearly describes the technical solutions of the present invention with reference to the accompanying drawings of embodiments. The described embodiments are merely some but not all of the embodiments of the present invention.

An embodiment of the present invention provides a display screen. The display screen includes a cathode metal layer, an encapsulating layer disposed on an upper surface of the cathode metal layer, and an organic light-emitting layer disposed on a lower surface of the cathode metal layer. A light shielding layer is added on a side of the upper surface of the cathode metal layer, and the light shielding layer is used to shield a non-light-emitting region of the organic light-emitting layer, to reduce ambient-light reflection from the cathode metal layer.

In an example, the display screen includes a cathode metal layer, an encapsulating layer disposed on an upper surface of the cathode metal layer, and an organic light-emitting layer disposed on a lower surface of the cathode metal layer, where the organic light-emitting layer includes a non-light-emitting region and a plurality of light-emitting regions. The display screen further includes a light shielding layer. The light shielding layer is disposed on an upper surface of the encapsulating layer, and the light shielding layer is used to shield the non-light-emitting region of the organic light-emitting layer. Disposition of the light shielding layer effectively reduces ambient-light reflection from the cathode metal layer, and allows a polarizer layer to be omitted, thereby resolving a problem of ambient-light reflection from the cathode metal layer by using a relatively small thickness, and avoiding a problem of relatively low transmittance caused by a polarizer layer.

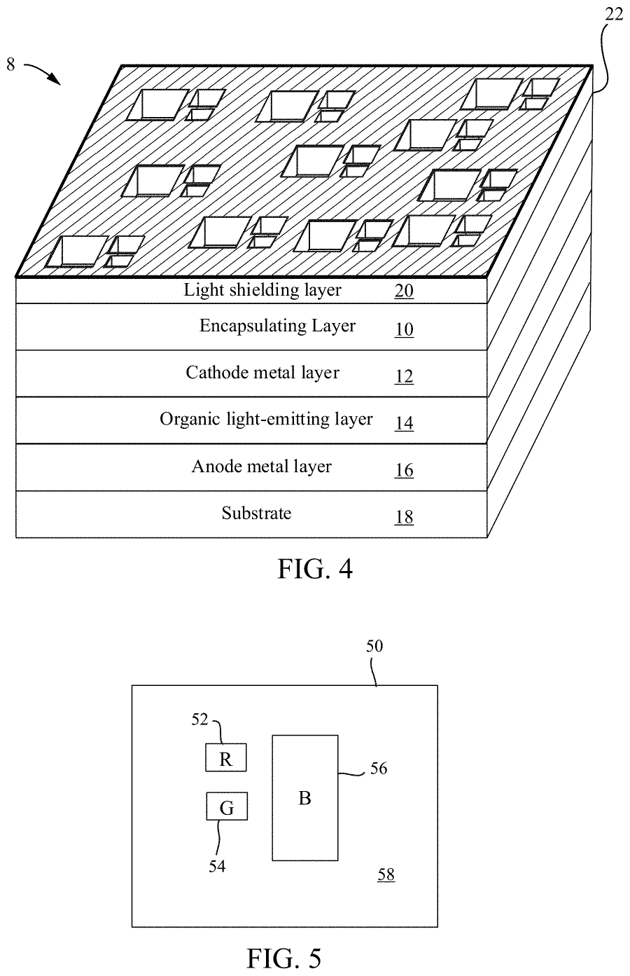

The following uses an OLED display screen as an example to further describe the technical solutions of the present invention with reference to the accompanying drawings and the embodiments. FIG. 4 is a schematic structural diagram of an OLED display screen 8 according to an embodiment of the present invention. As shown in FIG. 4, the display screen 8 includes an encapsulating layer 10, a cathode metal layer 12, an organic light-emitting layer 14, an anode metal layer 16, and a substrate 18. A light shielding layer 20 is further disposed on an upper surface 22 of the encapsulating layer 10, and the organic light-emitting layer 14 includes a non-light-emitting region and a plurality of light-emitting regions.

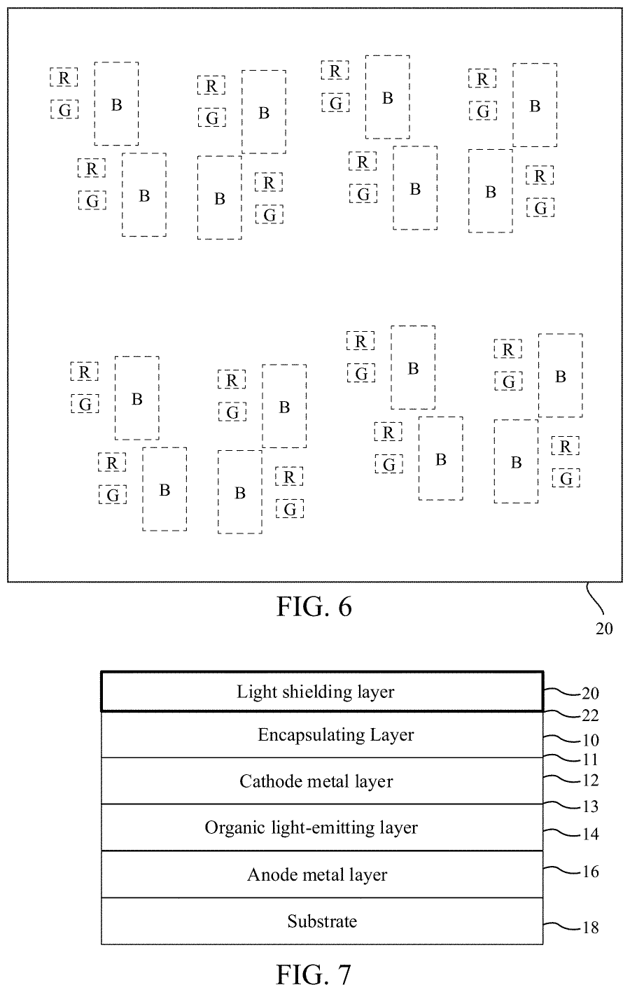

FIG. 5 is a schematic diagram of an OLED pixel structure 50. As shown in FIG. 5, R, G, and B are subpixel light-emitting regions 52, 54, 56, respectively, and a region 58 other than R, G, and B is a non-light-emitting region. FIG. 6 is a schematic top view of FIG. 4. As shown in FIG. 4, a shaded part is the light shielding layer 20. See also FIG. 6. The light shielding layer 20 shields the non-light-emitting region 58, and does not shield the light-emitting regions 52, 54, 56. In this way, ambient-light reflection from the cathode metal layer 12 can be effectively reduced. It should be understood that, based on a component design requirement, the light-emitting regions 52, 54, 56 may be regular or irregular, and both a quantity of the light-emitting regions of the organic light-emitting layer 14 and a position relationship between the light-emitting regions may be changed.

FIG. 7 is a sectional view of a structure of an OLED display screen that has a light shielding layer 20 according to an embodiment of the present invention.

In an example shown in FIG. 7, the display screen 8 includes a cathode metal layer 12, an encapsulating layer 10, and an organic light-emitting layer 14. The encapsulating layer 10 is located on an upper surface 11 of the cathode metal layer 12, and the organic light-emitting layer 14 is located on a lower surface 13 of the cathode metal layer. A light shielding layer 20 is located on an upper surface 22 of the encapsulating layer 10. The light shielding layer 20 shields a non-light-emitting region of the organic light-emitting layer 14, and does not shield a light-emitting region. In this way, ambient-light reflection from the cathode metal layer 12 can be effectively reduced.

In an example, a thickness of the light shielding layer 20 is 1 micrometer. Compared with a polarizer layer whose thickness is 100 micrometers, the light shielding layer 20 reduces a thickness of the display screen and improves a screen bending capability.

In an example, an optical density (optical density, OD) of the light shielding layer 20 is greater than or equal to 3.0.

In an example, the light shielding layer 20 is prepared through coating, vapor deposition, coating deposition, or thin-film attachment.

In an example, when the light shielding layer 20 is prepared through coating, after the upper surface of the encapsulating layer 10 is coated with the light shielding layer, a part that does not need to be shielded may be etched by using a photoetching method.

In an example, a material of the light shielding layer 20 is chromium or acryl resin.

In an example, carbon may be added to acryl resin.

In an embodiment, the light shielding layer 20 is located between the cathode metal layer 12 and the encapsulating layer 10.

An embodiment of the present invention provides a display screen, including an encapsulating layer 10, a light shielding layer 20, a cathode metal layer 12, and an organic light-emitting layer 14. The light shielding layer 20 is located between the encapsulating layer 10 and the cathode metal layer 12, the organic light-emitting layer 14 is located on a lower surface 13 of the cathode metal layer, the organic light-emitting layer includes a non-light-emitting region 58 and a plurality of light-emitting regions 52, 54, 56, and the light shielding layer is used to shield the non-light-emitting region of the organic light-emitting layer. Disposition of the light shielding layer 20 can also effectively reduce ambient-light reflection from the cathode metal layer 12, and allows omission of a polarizer layer, thereby resolving a problem of ambient-light reflection from the cathode metal layer by using a relatively small thickness, and avoiding a problem of relatively low transmittance caused by a polarizer.

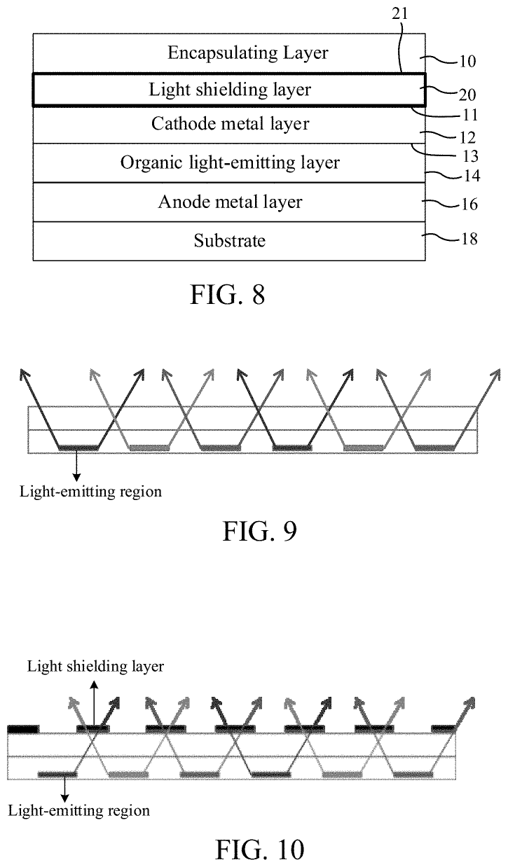

FIG. 8 is a sectional view of a structure of another OLED display screen that has a light shielding layer 20 according to an embodiment of the present invention.

In an example shown in FIG. 8, the display screen includes a cathode metal layer 12, an encapsulating layer 10, and an organic light-emitting layer 14. A light shielding layer 20 is located between the cathode metal layer 12 and the encapsulating layer 10 (the light shielding layer is located on an upper surface 11 of the cathode metal layer, and the organic light-emitting layer is located on a lower surface 13 of the cathode metal layer), and the encapsulating layer is located on an upper surface 21 of the light shielding layer. The light shielding layer 20 shields a non-light-emitting region 58 of the organic light-emitting layer 14, and does not shield a light-emitting region 52, 54, 56. In this way, ambient-light reflection from the cathode metal layer 12 can be reduced.

In an example, a thickness of the light shielding layer 20 is 1 micrometer. Compared with a polarizer layer whose thickness is 100 micrometers, the light shielding layer 20 reduces a thickness of the display screen and improves a screen bending capability.

In an example, an optical density (optical density, OD) of the light shielding layer 20 is greater than or equal to 3.0.

In an example, the light shielding layer 20 is prepared through coating, vapor deposition, coating deposition, or thin-film attachment.

In an example, when the light shielding layer 20 is prepared through coating, after the upper surface 11 of the cathode metal layer 12 is coated with the light shielding layer, a part that does not need to be shielded may be etched by using a photoetching method.

In an example, a material of the light shielding layer 20 is chromium or acryl resin.

In an example, carbon may be added to acryl resin.

In an example, the light shielding layers 20 in FIG. 7 and FIG. 8 may be deposited coatings. The deposited coating may be formed in any of a plurality of deposition processes, for example, a sputtering method, an electric arc vapor deposition method, and a vapor deposition method. When reading the specification, a person skilled in the art can select an appropriate deposition process based on a requirement to form a deposited coating used as an electrostatic discharge layer.

In another example, the light shielding layers 20 in FIG. 7 and FIG. 8 may be attached thin films. The attached thin film may be a thin film formed based on a plurality of materials and in a plurality of processes, for example, a PU thin film or a TPU thin film, and may be attached to a required surface.

Reflectivity curves of the light shielding layers 20 shown in FIG. 7 and FIG. 8 should be as flat as possible to avoid color cast of reflected light.

In the embodiments shown in FIG. 7 and FIG. 8, in addition to reducing the thickness of the display screen, disposition of the light shielding layer 20 can increase an aperture ratio of the OLED, to further increase brightness of the display screen. The aperture ratio is a ratio of a pixel light-emitting area to a total pixel area.

FIG. 9 is a schematic diagram showing light mixing caused by an increase in an aperture ratio. As shown in FIG. 9, specific gaps are reserved between subpixels RGB 52, 54, 56 of the OLED. If the gap is excessively small, subpixel light-emitting regions 52,54, 56 overlap with each other, and light mixing occurs in the RGB light-emitting regions. This affects a light-emitting effect. A pixel light-emitting area is a subpixel RGB area, an area of each light-emitting region is fixed, and a total pixel area is an area of the display screen.

FIG. 10 is a schematic diagram showing shielding a light mixing region by using a light shielding layer 20 to improve an aperture ratio. With reference to FIG. 9 and FIG. 10, in FIG. 9, for a same display screen, a total pixel area is unchanged. Therefore, to increase an aperture ratio, only an area of subpixel RGB regions 52, 54, 56 can be increased. The area of each light-emitting region 52, 54, 56 is fixed, and therefore, the only approach to increase aperture ratio is to reduce a size of gaps between light-emitting regions to increase a quantity of light-emitting regions, thereby increasing a total area of the light-emitting regions. In FIG. 10, after a size of gaps between light-emitting regions 52, 54, 56 is reduced, generated mixed light is blocked by a light shielding layer 20, and cannot be transmitted through a display screen. In this way, an aperture ratio is increased, and light mixing is prevented from affecting a display effect of the entire display screen.

Based on the foregoing technical solutions, an embodiment of the present invention further provides a terminal, including the display screen in any one of the foregoing embodiments.

In an example, the terminal may be a mobile phone, a wearable device such as a watch or glasses, or a tablet.

The foregoing descriptions are merely specific non-limiting implementations of the present invention, but are not intended to limit the protection scope of the present invention. Any variation or replacement readily understood by a person skilled in the art within the technical scope disclosed in the present invention shall fall within the protection scope of the present invention. Therefore, the protection scope shall be defined by the claims.

1. A display screen, comprising a cathode metal layer, an encapsulating layer disposed on an upper surface of the cathode metal layer, and an organic light-emitting layer disposed on a lower surface of the cathode metal layer, wherein the organic light-emitting layer comprises a non-light-emitting region and a plurality of light-emitting regions, wherein
the display screen further comprises a light shielding layer, the light shielding layer is disposed on an upper surface of the encapsulating layer, and the light shielding layer is used to shield the non-light-emitting region of the organic light-emitting layer.

2. The display screen according to claim 1, wherein an optical density of the light shielding layer is greater than or equal to 3.0.

3. The display screen according to claim 1, wherein a thickness of the light shielding layer is 1 micrometer.

4. The display screen according to claim 1, wherein a material of the light shielding layer is chromium or acryl resin.

5. The display screen according to claim 1, wherein the display screen is an organic light-emitting diode display screen.

6-13. (canceled)

14. A terminal, comprising a cathode metal layer, an encapsulating layer disposed on an upper surface of the cathode metal layer, and an organic light-emitting layer disposed on a lower surface of the cathode metal layer, wherein the organic light-emitting layer comprises a non-light-emitting region and a plurality of light-emitting regions, wherein
the display screen further comprises a light shielding layer, the light shielding layer is disposed on an upper surface of the encapsulating layer, and the light shielding layer is used to shield the non-light-emitting region of the organic light-emitting layer.

15. The terminal according to claim 14, wherein an optical density of the light shielding layer is greater than or equal to 3.0.

16. The terminal according to claim 14, wherein a thickness of the light shielding layer is 1 micrometer.

17. The terminal according to claim 14, wherein a material of the light shielding layer is chromium or acryl resin.

18. The terminal according to claim 14, wherein the display screen is an organic light-emitting diode display screen.

19. The terminal according to claim 14, wherein the terminal is at least one of a mobile phone, a wearable device, or a tablet.

20. A terminal, comprising an encapsulating layer, a light shielding layer, a cathode metal layer, and an organic light-emitting layer, wherein the light shielding layer is located between the encapsulating layer and the cathode metal layer, the organic light-emitting layer is located on a lower surface of the cathode metal layer, the organic light-emitting layer comprises a non-light-emitting region and a plurality of light-emitting regions, and the light shielding layer is used to shield the non-light-emitting region of the organic light-emitting layer.

21. The terminal according to claim 20, wherein an optical density of the light shielding layer is greater than or equal to 3.0.

22. The terminal according to claim 20, wherein a thickness of the light shielding layer is 1 micrometer.

23. The terminal according to claim 20, wherein a material of the light shielding layer is chromium or acryl resin.

24. The terminal according to claim 20, wherein the display screen is an organic light-emitting diode display screen.

25. The terminal according to claim 20, wherein the terminal is a mobile phone, a wearable device, or a tablet.
